(19) United States
(12) Patent Application Publication
(10) Pub. No.: US 2026/0206593 A1
(43) Pub. Date: Jul. 16, 2026

(54) SEMICONDUCTOR MODULE, OPERATING METHOD AND MANUFACTURING METHOD

(71) Applicant: Hitachi Energy Ltd, Zürich (CH)

(72) Inventors: Stephan WIRTHS, Thalwil (CH); Uwe DROFENIK, Zürich (CH); Ki-Bum PARK, Daejeon (KR); Lars KNOLL, Hägglingen (CH); Francisco Venustiano CANALES ABARCA, Baden-Dättwil (CH)

(21) Appl. No.: 19/135,979

(22) PCT Filed: Dec. 6, 2022
(86) PCT No.: PCT/EP2022/084618

§ 371 Date: Jun. 5, 2025

(51) Int. Cl. H10W 40/50; H03K 17/567; H10W 70/65; H10W 72/90; H10W 90/00

(52) U.S. Cl. CPC H10W 40/50; H10W 70/658; H10W 72/926; H10W 90/753; H10W 90/754; H03K 17/567

(57) ABSTRACT

In one embodiment, the semiconductor module includes a plurality of semiconductor devices and at least one bus line, wherein each of the semiconductor devices comprises a power semiconductor chip, a logic unit and a gate pad, each of the power semiconductor chips has a gate electrode contact area, in each one of the semiconductor devices, the logic unit is electrically placed between the gate electrode contact area and the gate pad, and the semiconductor devices are interconnected by means of the at least one bus line.

A semiconductor module and an operating method for such a module are provided. Further, a semiconductor device is also provided. Moreover, a method for manufacturing such a semiconductor device is provided as well.

Document EP 2 445 110 A1 refers to a gate driver unit for electrical switching devices.

Document US 2013/0200927 A1 discloses an over-temperature protected transistor.

A problem to be solved is to provide a robust semiconductor module that has improved thermal behavior.

This object is achieved, inter alia, by a semiconductor module, by an operating method, by a semiconductor device and by a manufacturing method as defined in the independent patent claims. Exemplary further developments constitute the subject-matter of the dependent claims.

For example, the semiconductor module described herein includes a plurality of semiconductor devices which are interconnected by a bus line. By means of logic units atop a power semiconductor chip in each one of the semiconductor devices in combination with the bus line, for example, equal temperatures of the power semiconductor chips across the semiconductor module can be ensured.

Paralleling of power semiconductor chips is limited due to asymmetric current sharing, asymmetric temperature and asymmetric loss distribution between the individual power semiconductor chips. Alternative solutions are, for example, using gate resistors which reduce switching speed and increase losses, a low-parasitics module design which space and performance limitations, a careful chip pre-selection which is expensive, or combinations of the aforementioned.

In the semiconductor module described herein, for example, an active controller implemented in CMOS on-chip logic is provided wherein the parallel power semiconductor chips share their average junction temperature as their control reference value. The proposed design is efficient to manufacture, robust, scalable, is easy-to-use, and has the potential to allow power modules with smaller footprint. It is proposed for SiC power semiconductor chips but would also work with other semiconductor materials like Si or GaN.

In at least one embodiment, the semiconductor module includes a plurality of semiconductor devices and at least one bus line, wherein
each of the semiconductor devices comprises a power semiconductor chip, a logic unit and a gate pad, each of the power semiconductor chips has a gate electrode contact area,
in each one of the semiconductor devices, the logic unit is electrically placed between the gate electrode contact area and the gate pad, and
the semiconductor devices are interconnected by means of the at least one bus line.

For example, there are at least four or at least ten of the semiconductor devices. Alternatively or additionally, there are at most 150 or at most 100 or at most 30 of the semiconductor devices. By way of example, the semiconductor module includes at least ten and at most 30 of the Semiconductor devices, like 16 semiconductor devices.

For example, the logic units are CMOS devices. The logic units do not need to be mechanically self-supported chips but can mechanically be carried by the power semiconductor chips. Thus, it is possible that the logic units are comparably thin and comprise only a small number of electric elements like resistors, transistors and capacitors. For example, the logic units each comprise at most 10⁵ or at most 10⁴ or at most 10³ such electric elements. A thickness of the logic units may be at least 0.2 μm and/or may be at most 10 μm or at most 3 μm.

For example, the gate pad and/or the gate electrode contact area are metallizations. That is, the gate pad and/or the gate electrode contact area can consist of one or more metals; for example, at least 98% by mass of the gate pad and/or the gate electrode contact area are metals.

For connecting renewables, batteries and electric vehicle charging stations to the medium-voltage grid, converters are needed which can switch KA currents beyond 10 kHz. To be able to handle current, voltage and switching frequency, it is required to parallel a large number of power semiconductor chips, like SiC chips, inside a corresponding semiconductor module.

The main challenge in doing so is that due to geometric asymmetries of the layout, packaging parasitics, chip tolerances and parameter variations, and temperature dependencies, the current and/or switching loss is not shared equally between the electrically parallel mounted power semiconductor chips, compare, for example, document A. Müsing, G. Ortiz and J. W. Kolar, “Optimization of the current distribution in press-pack high power IGBT modules,” The 2010 International Power Electronics Conference—ECCE ASIA—, 2010, pp. 1139-1146, doi: 10.1109/IPEC.2010.5543573. Hence, without further measures some power semiconductor chips will face much more current and temperature stress than others. With increasing chip number, the problem becomes worse. This limits the number of chips that can be mounted in parallel. In case of SiC, the individual chips are typically smaller as compared to Si chips, and more parallel SiC chips are needed which increases the problem.

Some solutions to this problem have limitations and/or come with high effort and/or high cost. Combinations of solutions as listed below may be employed:
With additional gate-resistors the switching speed is reduced to allow better switching loss distribution. On the other hand, this increases the overall-losses and reduces chip-performance.
Only chips with similar tolerance-related parameter deviations are preselected. This is time-and cost-intensive.
The module is carefully designed to minimize parasitics and cross couplings. Such optimizations are limited due to thermal conditions and, generally, space available in the module.
Active control would require chip-individual current Sensors, which are expensive, need space and add parasitic inductance. Furthermore, chip-individual gate signals would have to be employed with a lot of extra effort in wiring, interfacing and signal-processing if performed outside the power module in the gate driver.

In the semiconductor module described herein it is proposed to embed CMOS logic on top of the Sic power semiconductor chip right below the gate pad. A possible manufacturing process is also proposed. This would allow active current control of the individual power semiconductor chips for an arrangement of electrically parallel mounted chips.

All parallel mounted power semiconductor chips would get the same gate signal, and the switching speed and/or switching delay of the individual power semiconductor chips would be controlled by its individual CMOS logic unit. All parallel chips have, for example, a second pad, like the pad for the gate signal, to share junction temperature information on a dedicated module-internal signal wire, for example. In this case, chip-individual junction temperature is measured by its CMOS logic which can be very accurate due to the proximity to the junction. The logic unit is powered by the external gate signal, for example. If the proposed functionality is not employed and/or during power-up, when the logic unit is not activated, the SiC power semiconductor chips may behave according their characteristic parasitics distribution.

The parallel power semiconductor chips would automatically and actively start controlling their individual junction temperatures, but not necessarily current and/or losses, aiming for equal junction temperature, which would increase device lifetime and allow maximum power flow. This would work even in a non-optimum module design, and would, therefore, allow for footprint minimization. This also works for power semiconductor chips with tolerance-related parameter variations, that is, not pre-selected, and would, therefore, allow for cost minimization.

Furthermore, the number of parallel power semiconductor chips could be increased significantly. This would be especially beneficial for SiC-based power converters or converter cells in the lower megawatt-range. The proposed concept is not limited to SiC chips but can be applied to Si-based or GaN-based power semiconductor chips as well.

Advantageous characteristics of the semiconductor module and the semiconductor device described herein are, for example, are as follows, individually or in any combination:
Robust, scalable, easy-to-use;
simplified power module design possible with the potential of footprint reduction;
no additional terminals on the module required, access to average chip temperatures is optional;
a gate driver provides one single gate signal for all paralleled power semiconductor chips;
only one additional pad in the semiconductor device is required next to the gate signal pad for connecting the bus line displaying, for example, the average junction temperature;
on-chip power supply from gate signal is possible;
in case of disabling the control, like no power or no signal bus line connected, the power semiconductor chips will still work but behave according to their individual characteristics.

Hence, the semiconductor module and the semiconductor device described herein use, for example, the follow ideas, individually or in any combination:
Control logic in CMOS on-chip implementation;
connection of paralleled power semiconductor chips, especially single gate signal and single bus for calculating and sharing, for example, an average junction temperature;
adding one single additional pad on the semiconductor devices for sharing of the average junction temperature;
powering the CMOS logic unit via a gate driver signal;
placing the CMOS logic unit below the gate pad;
introducing a gate signal delay, for example, with controllable signal delay time implemented in a control function, instead of controlling an internal gate resistor;
employing the proposed controller in CMOS on-chip not only for SiC but also for Si and/or GaN power semiconductor chips;
employing the proposed controller alternatively in an external circuit with an CMOS on-chip temperature sensor and/or junction temperature estimation; and/or
adding a third pad onto the chip for optional reading the individual chip's junction temperature.

According to at least one embodiment, the gate pad is configured to provide the gate electrode contact areas of the semiconductor devices with a bus gate voltage. Thus, the gate pad can be connected with the gate electrode contact areas via the respective logic unit. Hence, there may be no direct electric contact between the gate electrode contact areas and the gate pad. For example, between the gate electrode contact areas and the gate pad there is at least one active electric component like a variable resistor and/or a switch.

According to at least one embodiment, in each one of the semiconductor devices the logic unit is configured to modify the bus gate voltage applied at the gate pad. Hence, the bus gate voltage can at least temporarily differ from a chip gate voltage applied at the gate electrode contact area, at least when the corresponding logic unit is provided with power and/or is active.

According to at least one embodiment, in each one of the semiconductor devices the logic unit is configured for a unit current through it of at most 1% of a chip current through the power semiconductor chip. For example, this value is at most 0.1%. By way of example, when turned on the unit current through the logic units is in each case at least 0.1 mA and/or is at most 0.02 A.

According to at least one embodiment, in each one of the semiconductor devices the logic unit is geometrically partially or completely located between the gate electrode contact area and the gate pad. For example, at least 50% or at least 80% or at least 95% of a volume of the respective logic unit is located between the assigned gate pad and the gate electrode contact area. Otherwise, the logic unit may be placed out of an interspace between the gate pad and the assigned gate electrode contact area.

According to at least one embodiment, the power semiconductor chips are each selected from the following group: a metal-insulator-semiconductor field-effect transistor, MISFET, a metal-oxide-semiconductor field-effect transistor, MOSFET, an insulated-gate bipolar transistor, IGBT, a reverse-conducting insulated-gate bipolar transistor, RC-IGBT.

All the power semiconductor chips in the semiconductor module can be of the same type, or there are different types of power semiconductor chips. The same applies for the logic units.

According to at least one embodiment, the power semiconductor chips are each configured for a voltage between a first electrode and a second electrode of the respective power semiconductor chip of at least 0.6 kV or of at least 1.2 kV and/or of at most 15 kV. Alternatively or additionally, the power semiconductor chips are each configured for a current between the first electrode and the second electrode of at least 1 A or of at least 0.01 kA or of at least 0.1 kA and/or of at most 100 kA or of at most 10 kA or of at most 1 kA. That is, by means of the gate electrode and by having the respective voltages between the first and second electrodes, a flow of current through the semiconductor device can be controlled, in particular can be switched on and off by turning on and off a voltage at the gate electrode.

According to at least one embodiment, in each one of the semiconductor devices the first electrode is a source electrode or an emitter electrode. Correspondingly, the second electrode is a drain electrode or a collector electrode of the respective power semiconductor chip.

According to at least one embodiment, in one or in some or in each one of the semiconductor devices the power semiconductor chip and the corresponding logic unit are of different semiconductor materials. For example, in one or in some or in each one of the semiconductor devices the power semiconductor chip is based on SiC and the logic unit is based on Si.

According to at least one embodiment, in one or in some or in each one of the semiconductor devices the power semiconductor chip is based on at least one of Si, SiC, GaN, GaO or diamond. Alternatively or additionally, in one or in some or in each one of the semiconductor devices the logic unit is based on at least one of Si, graphene, carbon nanotubes or perovskite.

According to at least one embodiment, seen in top view of the semiconductor devices, in one or in some or in all of the semiconductor devices the logic unit is smaller than or equal to a size of the gate pad. In other words, seen in top view, the size of the logic unit is at most the size of the gate pad.

According to at least one embodiment, the gate pad completely covers the logic unit. Hence, seen in top view, all of the logic unit is covered by the gate pad. This applies in one or in some or in all of the semiconductor devices.

According to at least one embodiment, at locations of the logic units in each case a distance between the respective gate electrode contact area and the gate pad is at most 1 μm or is at most 2 μm or is at most 5 μm. This applies in one or in some or in all of the semiconductor devices. Alternatively or additionally, said distance is at least 0.2 μm or is at least 1 μm. Accordingly, the logic units can be very thin.

According to at least one embodiment, in one or in some or in each one of the semiconductor devices the logic unit comprises one or a plurality of sensors. For example, the sensor is a temperature sensor or a voltage sensor or a current sensor or a magnetic field sensor. Any of these sensors can be combined with each other if there is a plurality of the sensors. There can be more than one sensor of the same type. The sensor or some of the sensors or all of the sensors are configured to generate a sensor signal. For example, per sensor one sensor signal is generated.

According to at least one embodiment, the sensor or at least one of the sensors is a temperature sensor. For example, said at least one sensor comprises or is a temperature-dependent electric resistor. Said resistor can have a positive or also a negative temperature characteristic, that is, with increasing temperature the electric resistance can increase or also decrease, respectively.

According to at least one embodiment, the respective logic unit is configured to output the sensor signal on the bus line. Accordingly, per sensor there can be one sensor signal on the bus line. The sensor signals, for example, one sensor signal per semiconductor device, can simultaneously be outputted so that an averaged or superimposed signal is on the bus line. Otherwise, it is also be possible that the sensor signals are outputted in a time-division multiplexing manner, that is, displaced in time.

For example, the sensor signals are directly outputted, for example, as a voltage value. However, it is also possible that the sensor signals are outputted in a modulated or converted manner. For example, a value of the respective sensor signal, like a voltage, can be converted in a current and/or may be coded as a frequency of an output signal.

According to at least one embodiment, the at least one bus line includes a first bus line and a second bus line which are electrically separated from one another. It is possible that the bus line consists of the first and second bus lines and, thus, has exactly two channels or cores. Accordingly, the bus line may be a two-core connection or cable.

Otherwise, it is also possible that the bus line consists of only one channel and may be a one-core connection or cable.

According to at least one embodiment, the first bus line interconnects all the gate pads of the semiconductor devices. It is possible that the first bus line is exclusively used for providing a gate voltage to the gate pads; in this case, the first bus line intentionally does not carry any other signals, like the sensor signals.

According to at least one embodiment, the logic units in some or in all of the semiconductor devices comprise a sensor pad. The second bus line interconnects these sensor pads. It is possible that the second bus line is exclusively used for carrying the sensor signals so that the second bus line may not be provided with the gate voltage.

According to at least one embodiment, in one or in some or in each one of the semiconductor devices the logic unit is configured to adjust a temperature of a junction of the corresponding power semiconductor chip. This is done, for example, by adapting a turn-on time of said power semiconductor chip. The turn-on time, and likewise a turn-off time, may be adapted by having a variable resistor between the gate pad and the gate electrode contact area, said variable resistor is part of the respective logic unit and can be adjusted by said logic unit, for example.

A method for operating the semiconductor module is additionally provided. By means of the method, a semiconductor module is operated as indicated in connection with at least one of the above-stated embodiments. Features of the semiconductor module are therefore also disclosed for the operating method and vice versa.

In at least one embodiment, the operating method is for a semiconductor module and comprises at least the following steps, for example, in the stated order:
sensing the power semiconductor chips by means of the sensors,
outputting the sensor signals on the bus line,
controlling the temperatures of the junctions of the power semiconductor chips so that these temperatures are all the same, for example, with a tolerance of at most 5 K or of at most 10 K or of at most 20 K.

A semiconductor device for the semiconductor module is additionally provided. The semiconductor module includes one or a plurality of the semiconductor devices. Features of the semiconductor module are therefore also disclosed for the semiconductor device and vice versa.

In at least one embodiment, the semiconductor device is configured for a semiconductor module and comprises:
a power semiconductor chip having a gate electrode contact area,
a logic unit, and
a gate pad configured for externally contacting the semiconductor device,
   wherein the logic unit is at least partially located between the at least one power semiconductor chip and the gate pad.

A method for manufacturing the semiconductor device is additionally provided. By means of the method, a semiconductor device is produced as indicated in connection with at least one of the above-stated embodiments. Features of the semiconductor device are therefore also disclosed for the manufacturing method and vice versa.

In at least one embodiment, the method is for manufacturing a semiconductor device and comprises at least the following steps, for example, in the stated order:
providing the power semiconductor chip and the logic unit,
bonding the logic unit onto the power semiconductor chip, in particular by wafer bonding, and
applying the gate pad over the logic unit.

A semiconductor module, a semiconductor device, an operating method and a manufacturing method described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the figures:

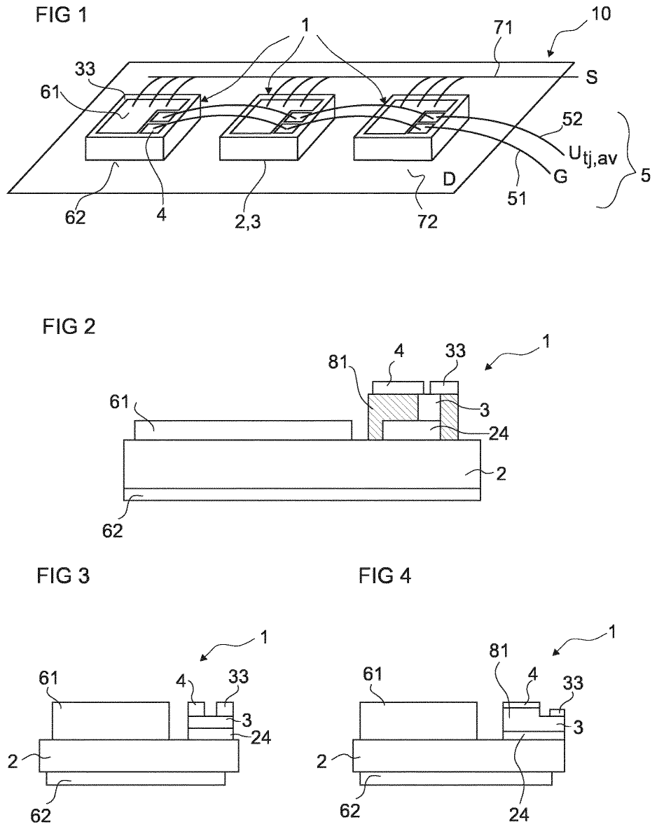

FIG. 1 is a schematic perspective view of an exemplary embodiment of a semiconductor module comprising semiconductor devices described herein,

FIGS. 2 to 4 are schematic sectional views of exemplary embodiments of semiconductor devices described herein,

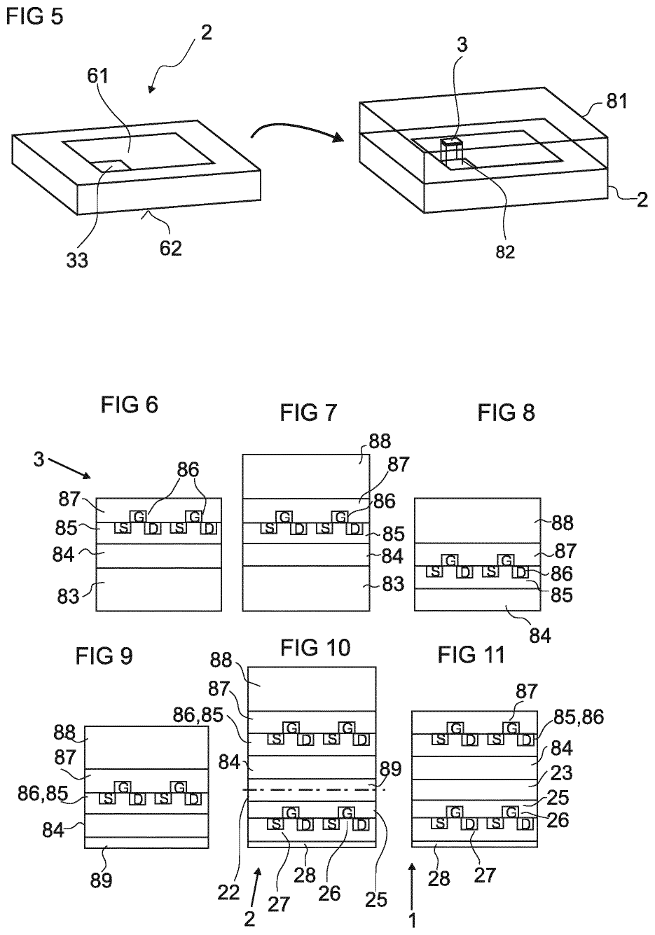

FIG. 5 is a schematic perspective view of an exemplary embodiment of a semiconductor device described herein,

FIGS. 6 to 11 are schematic sectional views of method steps of an exemplary method for producing semiconductor devices described herein,

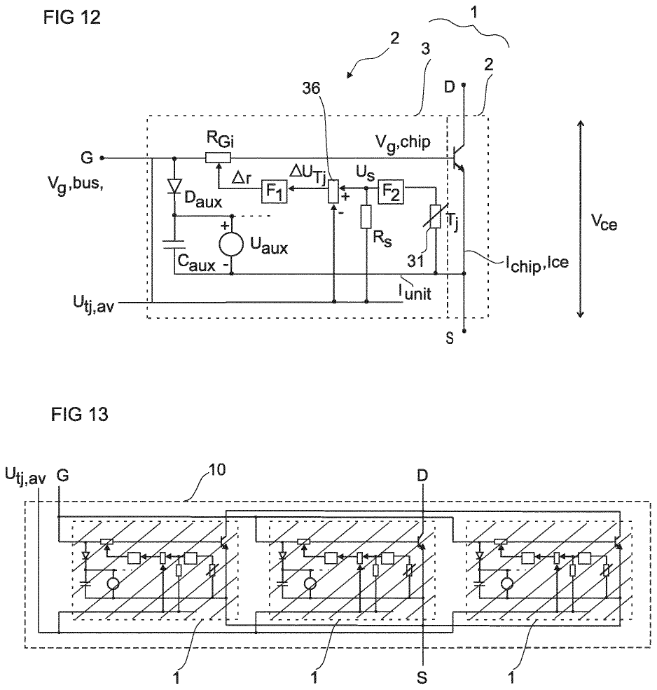

FIG. 12 is a schematic circuit diagram of an exemplary embodiment of a semiconductor device described herein, and

FIG. 13 is a schematic diagram of an electric wiring of an exemplary embodiment of a semiconductor module comprising semiconductor devices described herein.

In FIG. 1, an exemplary embodiment of a semiconductor module 10 is illustrated. The semiconductor module 10 comprises a plurality of semiconductor devices 1. By way of example, only three of the semiconductor devices 1 are shown in FIG. 1, but the semiconductor module 10 can comprise much more of the semiconductor devices 1. For example, if there are more of the semiconductor devices 1, they can be arranged in a two-dimensional array, like a 4×4 array. Although in FIG. 1 all the semiconductor devices 1 are of equal design, it is also possible to combine different kinds of semiconductor devices 1 within the semiconductor module 10.

For example, the semiconductor devices 1 are all mounted with their second electrodes 62 on a common second power line 72 of the semiconductor module 10. The second power line 72 can be, for example, an areal metallization of a circuit board, like a metal-insulator-metal board. The second power line 72 is possibly a contact for a drain D. First electrodes 61 of the semiconductor devices 1 on sides remote from the second power line 72 are electrically connected to a first power line 71 which may also be located on the circuit board and which may be a contact for a source S. For example, the first power line 71 is in each case connected with the first electrodes 61 by a couple of bond wires.

Seen in top view, the first electrodes 61 can be of L-shape. In a free corner of the L, there is in each case a gate pad 4 and a sensor pad 33 which are realized by metallizations, for example. The gate pad 4 and the sensor pad 33 can be next to one another and can be of the same size and shape or indeed of different sizes and/or shapes.

All the gate pads 4 are interconnected by a first bus line 51 of a bus line 5. By means of the first bus line 51, a voltage Vg,bus for gates G of the semiconductor devices 1 is provided. Further, the sensor pads 33 are interconnected by a second bus line 52 of the bus line 5. By means of the second bus line 52, at least one sensor signal Utj,av for logic units 3 of the semiconductor devices 1 is provided.

The first bus line 51 is electrically separated from the second bus line 52. Each one of the bus lines 51, 52 can be realized by a chain of bond wires interconnected by means of the signal pads 33 and the gate pads 4, respectively. Hence, the bus lines 51, 52 can each be of a single electric line.

For example, a filling factor of the semiconductor devices 1 on the second power line 72 is at least 20% or is at least 50% and/or is at most 90% or is at most 70%. The filling factor is, for example, a quotient of an area of all the semiconductor devices 1 together and an area content within a shortest close line enclosing all the semiconductor devices 1, and seen in top view. That is, the semiconductor devices 1 can be arranged relatively close to one another.

Some examples of internal configurations of the semiconductor devices 1 are illustrated in FIGS. 2 to 4. In each case, the semiconductor devices 1 comprise a power semiconductor chip 2 having a gate electrode contact area 24 as well as the first and second electrodes 61, 62. Further, the semiconductor devices 1 each comprise a logic unit 3, like a CMOS-device, wherein CMOS means Complementary Metal-Oxide-Semiconductor. For example, the gate pads 4 are completely or partly arranged atop the assigned gate electrode contact area 24.

The logic units 3 are geometrically located partially or completely between the assigned gate pad 4 and gate electrode contact area 24. However, it is alternatively possible that the logic units 3 are placed outside a space between the pairs of gate electrode contact areas 24 and gate pads 4, and further it is alternatively or additionally possible that the gate pads 4 do not cover the assigned gate electrode contact areas 24, seen in top view.

Other than illustrated in FIGS. 1 to 4, the pads 4, 33 do not need to be located at a corner of the semiconductor device 1, seen in top view, but may also be located centrally on the power semiconductor chip 2 so that the first electrode 61 may surround these pads 4, 33 or at least one of these pads 4, 33. That is, one of the pads 4, 33 may be placed centrally while the other one may be placed at an edge or in a corner of the power semiconductor chip 2, seen in top view.

According to FIG. 2, the logic unit 3 covers only part of the gate electrode contact area 24. Moreover, the logic unit 3 is embedded in an electrically insulating material 81. The electrically insulating material 81 and the logic unit 3 may terminate level with each other on a side facing away from the power semiconductor chip 2. On top of the logic unit 3 and the electrically insulating material 81, there are the pads 4, 33.

Other than shown, it is also possible that either one or both of the pads 33, 4 are completely located on the logic unit 3. Further, it is possible that either one or both of the pads 33, 4 are completely located within the gate electrode contact area 24, seen in top view. As shown in FIG. 2, the signal pad 33 is partially or also completely located outside the gate electrode contact area 24, seen in top view.

Further, as still shown in FIG. 2, the pads 4, 33 may protrude over the first electrode 61, seen in cross-section. That is, a thickness of the first electrode 61 may be smaller than a thickness of the stack of the components 24, 3, 4, 33. Optionally, the second electrode 62 may completely or virtually completely cover a side of the power semiconductor chip 2 remote from the logic unit 3.

In the embodiment of FIG. 3, the logic unit 3 is congruent with the gate electrode contact area 24, seen in top view.

Thus, the electrically insulating material 81 of FIG. 2 may be omitted. Moreover, the stack of the gate electrode contact area 24, the logic unit 3 and the pads 4, 33 may have the same thickness as the first electrode 61 so that the pads 4, 33 and the first electrode 61 are level with each other. The pads 4, 33 can completely be located atop the logic unit 3. It is possible that the second electrode 62 at a bottom side of the power semiconductor chip 2 does not reach edges of the bottom side. These modifications are also possible in the semiconductor device 1 of FIG. 2.

According to FIG. 4, the pads 4, 33 are at different heights over the power semiconductor chip 2. Hence, the logic unit 3 may be of stepped manner.

Otherwise, the same as to FIG. 1 may also apply to FIGS. 2 to 4, and vice versa.

In FIG. 5, the design of the semiconductor device 1 is illustrated from a manufacturing point of view. In the left of FIG. 5, the power semiconductor chip 2 is shown. The gate electrode contact area 24 and the first electrode 61 can terminate flush with each other in a direction away from a semiconductor body of the power semiconductor chip 2.

Then, see FIG. 5 on the right, the electrically insulating material 81 is applied, for example, completely over the power semiconductor chip 2. The logic unit 3 is applied on the electrically insulating material 81. The pads 33, 4 are not illustrated in FIG. 5 for simplification of the drawing.

Moreover, the logic unit 3 and the gate electrode contact area 24 may be connected by means of one or a plurality of electrical through-connections 82 through the electrically insulating material 81. Not shown, atop the first electrode 61 there can also be a plurality of electrical through-connections 82 to connect the first electrode 61 with the first power line 71 as illustrated in FIG. 1.

In FIGS. 6 to 11, a manufacturing method of the semiconductor devices 1 is illustrated in more detail. According to FIG. 6, the logic unit 3 is provided. For example, the logic unit 3 comprises a first carrier 83 which can be of Si and which may be regarded a donor. The first carrier 83 is followed by a first insulation layer 84 which is, for example, a buried oxide layer, like a silicon dioxide layer. Then, there is a logic unit functional semiconductor layer 85 made, for example, of Si. In this layer 85 at least one logic structure 86 is formed. The logic structure 86 comprises, for example, a plurality of FETs. Finally, atop the logic structure 86 there is a second insulation layer 87, for example, of silicon dioxide.

As shown in FIG. 7, atop the second insulation layer 87, a second carrier 88, like a silicon handling substrate, is attached. Then, see FIG. 8, the first carrier 83 is removed so that the first insulation layer 84 is exposed.

In the step of FIG. 9, a first connection layer 89 is applied on the first insulation layer 84. For example, the first connection layer 89 is of silicon nitride and, thus, shares a main component of the crystal lattices of the power semiconductor chip 2 and of the logic unit 3 which are, for example, of SiC and Si, respectively.

In the step of FIG. 10, the power semiconductor chip 2 is provided. In this exemplary embodiment, the power semiconductor chip 2 comprises a power chip functional semiconductor layer 27 which is made, for example, of 4H—SiC. The power chip functional semiconductor layer 27 is provided with a chip structure 26 which comprises, for example, transistor units, which are only schematically illustrated in a very simplified manner, like the logic structure 86. For example, the power chip functional semiconductor layer 27 and the chip structure 26, respectively, include a source region, a plug region, a well region, a drift region, a gate insulator, a gate electrode structure and a first electrode structure corresponding to the first electrode 61, not shown, so that the chip structure 26 may correspond to a FET or a IGBT.

At a side of the power chip functional semiconductor layer 27 remote from the chip structure 26, optionally there is at least one additional semiconductor layer 28 which is, for example, a buffer layer and a drain layer or a collector layer. Further, at the side of the additional semiconductor layer 28 there can be the second electrode, not shown.

The chip structure 26 is covered by a top insulation layer 25, like a silicon dioxide layer. The top insulation layer 25 is followed by a second connection layer 22. The first and second connection layers 22, 89 are of the same material, for example. These layers 22, 89 are to be connected with each other at a common interface, illustrated as a dashed line, for example, by means of wafer bonding.

The resulting semiconductor device 1 is illustrated in FIG. 11. Hence, the power semiconductor chip 2 and the logic unit 3 are connected with each other by the overall connection layer 23 which is composed of the first and second connection layers 22, 89.

In FIG. 11, neither electrical through-connections 82 nor electrodes 61, 62, 24 nor pads 33, 4 are shown. However, the pads 33, 4 and the first electrode 61 can be present at a side of the second insulation layer 87 remote from the chip structure 26, and there can be electrical through-connections 82 from the first electrode 61 to the chip structure 26 as well as electrical through-connections 82 from the pads 33, 4 to the logic structure 86.

Hence, an exemplary method to produce the semiconductor device 1 may be summarized as follows:
First, the processed CMOS-SOI wafer 83, 84, 85, 86 is covered with SiO₂ using, for example, plasma-enhanced chemical vapor deposition, PECVD. Due to a surface topography, a chemical mechanical polishing, CMP, step may be required, see also FIG. 6. Next, a Si handling wafer 88 is bonded on top of the oxide 87, see also FIG. 7, since the Si donor wafer 83 on the bottom is etched away using TMAH in a subsequent step as illustrated in FIG. 8. After removing the buried oxide, BOX, layer 84 wet chemically, for example, using HF, SiO₂ and Si₃N₄ layers 84, 89 are deposited again using PECVD as depicted in FIG. 9.

Following standard SiC power chip wafer fabrication, the 4H—SiC power devices 28, 27, 26 will be covered with SiO₂ and Si₃N₄ layers 25, 22, for example, using PECVD. Both the Si CMOS 85, 86, 87 and the SiC power wafer 28, 27, 26 are finally bonded on top of each other at the Si₃N₄ layers 22, 89 and the Si handling wafer 88 can be etched, compare FIGS. 10 and 11.

Regarding the wafer bonding process of FIGS. 10 and 11, there are several major methods available such as wafer-to-wafer or dice-to-wafer molecular/direct wafer bonding, benzocyclobutene-assisted dice-to-wafer adhesive bonding or metal-assisted adhesive bonding. The latter technique may not be applicable due to potential metal contamination. The method of choice would be a pick-and-place technology based on dice-to-wafer direct wafer bonding due to low thermal budget, for example, 3 h at 250° C., O₂ plasma-assisted, and high accuracy, like small misalignment tolerances of ±5 μm, can be achieved.

Otherwise, the same as to FIGS. 1 to 5 may also apply to FIGS. 6 to 11, and vice versa.

In FIG. 12, an exemplary circuit structure of the semiconductor device 1 is illustrated. As input for the logic unit 3, there is the gate line G providing the bus gate voltage Vg,bus and the signal line Utj,av providing, for example, an average junction temperature voltage of all the connected semiconductor devices 1. The bus gate voltage Vg,bus is adjusted to become a chip gate voltage Vg,chip by means of a variable internal gate resistor RGi. A resistance of the gate resistor RGi is adjusted by means of a sensor signal UTj representing a junction temperature Tj of the power semiconductor chip 2 by means of a sensor 31 which is a temperature-dependent resistor, for example.

By a function F2 the temperature-dependent resistance of the sensor 31 is converted into a voltage, that is, the sensor signal UTj. The sensor signal UTj is provided to the signal line Utj,av via a sensor resistor Rs and also to an adder/subtractor 36 at which the signal line Utj,av is another input. The adder/subtractor 36 outputs a junction temperature deviation ΔUTj which is converted by a function F1 into a change in resistance Δr to be applied to the internal gate resistor RGi.

The logic unit 3 is powered, for example, by means of an auxiliary power unit which may comprise an auxiliary capacitor Caux and an auxiliary diode Daux resulting in an auxiliary voltage Uaux. The auxiliary power unit is powered by the bus gate voltage Vg,bus against the source S which may be at ground voltage, for example.

For example, as in all other embodiments, the power semiconductor chip 2 can be a power FET or a power IGBT based on SiC, Si or GaN and may be configured for a current Ice between the first and second electrodes 61, 62 corresponding to S and D of around 0.1 kA at a voltage Vce of, for example, 1.2 kV. A current Iunit through the logic unit 3 is, for example, about 10 mA. A maximum bus gate voltage Vg,bus is, for example, around 15 V.

Thus, the semiconductor devices 1 described herein and used for the semiconductor modules 10 include a controller as the logic unit 3 with following characteristics, for example: The controller 3 is implemented as CMOS logic circuit on-chip below the gate pad 4 of the assigned power semiconductor chip 2. A temperature sensor 31, which is integrated into the CMOS logic 3, measures the power semiconductor chip junction temperature Tj which is converted via a controller F2 into a voltage signal UTj. Voltage UTj is connected via an impedance Rs to a voltage Utj,av which is accessed via the additional sensor pad 33 next to the gate pad 4. When such SiC power chips 2 are connected via this bus, the bus voltage Utj,av represents the average junction temperature of all connected chips 2. The controller 3 compares Utj,av with its internal junction temperature, represented by UTj, calculates the error ΔUTj, and converts ΔUTj by control function F2 into control signal Δr which defines the internal gate resistor RGi of the Sic chip 2 accordingly.

In FIG. 13 it is illustrated how a plurality of the semiconductor devices 1, like three of them, is wired in the semiconductor module 10, compare also FIG. 1.

Otherwise, the same as to FIGS. 1 to 11 may also apply to FIGS. 12 and 13, and vice versa.

Thus, with the semiconductor module 10 described herein, symmetric current sharing of Sic power semiconductor chips 2 using CMOS-on-chip junction temperature controllers 3 is enabled.

Although in the embodiments reference is made to sources S and drains D, however in each case emitters and collectors can alternatively be present, if the power semiconductor chips 2 are IGBTs instead of FETs.

In the embodiments above, the logic unit 3 is integrated in the semiconductor devices 1. However, alternatively the logic unit 3 may be employed in an external circuit with a CMOS on-chip temperature sensor and/or junction temperature estimation.

Further, it is possible in all the embodiments to add a third pad onto the semiconductor devices 1, in addition to the electrodes 61, 62 and the pads 33, 4, for optional reading the individual chip's junction temperature.

The components shown in the figures follow, unless indicated otherwise, exemplarily in the specified sequence directly one on top of the other. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

### LIST OF REFERENCE SIGNS

1 semiconductor device
2 power semiconductor chip
22 second connection layer
23 overall connection layer
24 gate electrode contact area
25 top insulation layer
26 chip structure
27 power chip functional semiconductor layer
28 additional semiconductor layer
3 logic unit
31 sensor
33 sensor pad
36 adder/subtractor
4 gate pad
5 bus line
51 first bus line
52 second bus line
61 first electrode (source electrode or emitter electrode)
62 second electrode (drain electrode or collector electrode)
71 first power line
72 second power line
81 electrically insulating material
82 electrical through-connection
83 first carrier
84 first insulation layer
85 logic unit functional semiconductor layer
86 logic structure
87 second insulation layer
88 second carrier
89 first connection layer
10 semiconductor module
Caux auxiliary capacitor
D drain
Daux auxiliary diode
FX function
G gate
Ice current between the first and second electrode
Iunit unit current through the logic unit
RGi variable internal gate resistor
Rs sensor resistor
S source
Tj junction temperature
Uaux auxiliary voltage
UTj sensor signal
Utj,av average sensor signal
Vce voltage between the first and second electrode
Vg,bus bus gate voltage
Vg,chip chip gate voltage
Δr change in resistance
ΔUTj junction temperature deviation

1. A semiconductor module having semiconductor devices and at least one bus line, wherein:
each of the semiconductor devices comprises a power semiconductor chip, a logic unit and a gate pad, each of the power semiconductor chips has a gate electrode contact area,
in each one of the semiconductor devices, the logic unit is electrically placed between the gate electrode contact area and the gate pad, and
the semiconductor devices are interconnected by means of the at least one bus line.

2. The semiconductor module according to claim 1, wherein the gate pad is configured to provide the gate electrode contact areas of the semiconductor devices with a bus gate voltage (Vg), wherein in each one of the semiconductor devices:
the logic unit is configured to modify the bus gate voltage (Vg,bus) at the gate pad so that the bus gate voltage (Vg) differs from a chip gate voltage (Vg,chip) applied at the gate electrode contact area,
the logic unit is configured for a unit current (Iunit) through it of at most 1% of a chip current (Ice) through the power semiconductor chip, and
in each one of the semiconductor devices, the logic unit is geometrically at least partially located between the gate electrode contact area and the gate pad.

3. The semiconductor module according to claim 1,
wherein the power semiconductor chips are each selected from the group comprising: a metal-insulator-semiconductor field-effect transistor, MISFET, a metal-oxide semiconductor field-effect transistor, MOSFET, an insulated-gate bipolar transistor, IGBT, a reverse-conducting insulated-gate bipolar transistor, RC-IGBT,
wherein the power semiconductor chips are each configured for a voltage (Vce) between a first electrode and a second electrode of the respective power semiconductor chip of at least 0.6 kV and of at most 15 kV, and are further configured for a current (Ice) between the first electrode and the second electrode of at least 1 A, and
wherein in each case the first electrode is a source electrode or an emitter electrode and the second electrode is a drain electrode or a collector electrode of the respective power semiconductor chip.

4. The semiconductor module according to claim 1, wherein in each one of the semiconductor devices the power semiconductor chip and a corresponding logic unit are of different semiconductor materials.

5. The semiconductor module according to claim 4, wherein in each one of the semiconductor devices the power semiconductor chip is based on at least one of Si, SiC, GaN, GaO or diamond, and the logic unit is based on at least one of Si, graphene, carbon nanotubes or perovskite.

6. The semiconductor module according to claim 5, wherein in each one of the semiconductor devices the power semiconductor chip is based on SiC and the logic unit is based on Si.

7. The semiconductor module according to claim 1, wherein, seen in top view of the semiconductor devices, in each case the logic unit is smaller than or equal to a size of the gate pad, and the gate pad completely covers the logic unit.

8. The semiconductor module according to claim 1, wherein at locations of the logic units in each case a distance between the respective gate electrode contact area and the gate pad is at most 2 μm.

9. The semiconductor module according to claim 1, wherein in each one of the semiconductor devices the logic unit comprises at least one sensor which is configured to generate at least one sensor signal (UTj).

10. The semiconductor module according to claim 9, wherein the sensor or at least one of the sensors is a temperature sensor which comprises a temperature-dependent electric resistor.

11. The semiconductor module according to claim 9, wherein the logic unit is configured to output the sensor signal (UTj) on the bus line.

12. The semiconductor module according to claim 9,
wherein the at least one bus line includes a first bus line and a second bus line which are electrically separated from one another,
wherein the first bus line interconnects all the gate pads of the semiconductor devices, and
wherein the logic units in each case comprise a sensor pad and the second bus line interconnects all the sensor pads.

13. The semiconductor module according to claim 1, wherein in each one of the semiconductor devices the logic unit is configured to adjust a temperature of a junction of a corresponding power semiconductor chip by adapting a turn-on time of said power semiconductor chip.

14. An operating method for a semiconductor module, the operating method comprising the following steps:
given a semiconductor module comprising semiconductor devices and at least one bus line, wherein:
each of the semiconductor devices comprises a power semiconductor chip, a logic unit and a gate pad, each of the power semiconductor chips has a gate electrode contact area,
in each one of the semiconductor devices, the logic unit is electrically placed between the gate electrode contact area and the gate pad, and
the semiconductor devices are interconnected by means of the at least one bus line, wherein in each one of the semiconductor devices the logic unit comprises at least one sensor which is configured to generate at least one sensor signal (UTi),
sensing the power semiconductor chips by means of the sensors, outputting the sensor signals (UTj) on the bus line; and
controlling the temperatures of the junctions of the power semiconductor chips so that these temperatures are all the same with a tolerance of at most 10 K.

15. A semiconductor device configured for a semiconductor module that comprises semiconductor devices and at least one bus line, wherein:
each of the semiconductor devices comprises a power semiconductor chip, a logic unit and a gate pad, each of the power semiconductor chips has a gate electrode contact area,
in each one of the semiconductor devices, the logic unit is electrically placed between the gate electrode contact area and the gate pad, and
the semiconductor devices are interconnected by means of the at least one bus line, the semiconductor device comprising:
a power semiconductor chip having a gate electrode contact area;
a logic unit; and
a gate pad configured for externally contacting the semiconductor device by means of the at least one bus line, wherein the logic unit is at least partially located between the power semiconductor chip and the gate pad.

16. A method for manufacturing a semiconductor device according to claim 15, the method comprising the steps:
providing power semiconductor chip and a logic unit;
bonding the logic unit onto the power semiconductor chip, by wafer bonding; and
applying the gate pad over the logic unit, wherein the semiconductor device is configured for a semiconductor module that comprises semiconductor devices and at least one bus line, wherein:
each of the semiconductor devices comprises a power semiconductor chip, a logic unit and a gate pad, each of the power semiconductor chips has a gate electrode contact area,
in each one of the semiconductor devices, the logic unit is electrically placed between the gate electrode contact area and the gate pad, and
the semiconductor devices are interconnected by means of the at least one bus line, the semiconductor device comprising:
a power semiconductor chip having a gate electrode contact area;
a logic unit; and
a gate pad configured for externally contacting the semiconductor device by means of the at least one bus line, wherein the logic unit is at least partially located between the power semiconductor chip and the gate pad.

17. An operating method for a semiconductor module according to claim 13, the method comprising the following steps:
sensing the power semiconductor chips by means of the sensors, outputting the sensor signals (UTj) on the bus line, and
controlling the temperatures of the junctions of the power semiconductor chips so that these temperatures are all the same with a tolerance of at most 10 K.
